(19) United States
(12) Patent Application Publication
(10) Pub. No.: US 2019/0271744 A1
(43) Pub. Date: Sep. 5, 2019

(54) APPARATUS AND METHOD FOR MONITORING THE POWER USAGE STATUS OF A BATTERY UNIT

(71) Applicant: Yung-Sheng Huang, Taipei (TW)

(72) Inventor: Yung-Sheng Huang, Taipei (TW)

(21) Appl. No.: 16/415,055

(22) Filed: May 17, 2019

Related U.S. Application Data
(63) Continuation-in-part of application No. 15/236,614, filed on Aug. 15, 2016, now abandoned.

(51) Int. Cl. G01R 31/367; G01R 31/371; G01R 31/392

(52) U.S. Cl. CPC G01R 31/367; G01R 31/392; G01R 31/371

(57) ABSTRACT

A method and apparatus is proposed for monitoring the power usage status of a battery unit, including the remaining volume and the remaining capacity of the battery unit as well as the usage and recycling status of the battery unit. The proposed method and apparatus is characterized in that it is capable of detecting the remaining volume and the remaining capacity of the battery unit quickly in a very short instant of time after the startup of the battery unit.

### CROSS-REFERENCE TO RELATED APPLICATIONS

This application is a continuation in part of U.S. patent application Ser. No. 15/236,614 entitled “TRACKABLE BATTERY APPARATUS AND METHOD OF TRACKING SAME” filed Aug. 15, 2016 which is incorporated by reference for all purposes, and is now pending.

### BACKGROUND OF THE INVENTION

### 1. Field of the Invention

The invention relates to battery management technology, and more particularly to a method and apparatus for monitoring the power usage status of a battery unit, including the remaining volume (RV) and the remaining capacity (RC) of the battery unit as well as the recycling status of the battery unit.

### 2. Description of Related Art

In the use of a battery unit, such as one used for powering an electric car, an electric motorcycle, a notebook computer, a mobile phone, or any mobile electronic device, it is important for the user to know the remaining volume or the remaining capacity of the battery unit at any time of use, so that if the battery power is about to be completely consumed or is no longer usable and should be discarded for recycling, the user can promptly recharge or replace the battery unit.

Presently, there are many existing conventional technologies that can detect the remaining volume or remaining capacity of a battery unit. For example, on a mobile phone, a battery power indicator is provided to show the usable remaining battery power, such as showing 5% that indicates that the remaining battery power is only 5% of the fully charged volume. One drawback of this conventional technology, however, is that the detection of the remaining battery power requires the discharge of a very large load current and voltage, up to 25 A and 10.5V, at a temperature of 25° C., which takes a relative long period of time to achieve. In the case of a battery unit on an electric car, it is important for the user to be immediately informed of the usable remaining volume or remaining capacity of the battery unit at the startup of the electric car. However, the conventional technologies would require a relatively very long time to detect the remaining volume or remaining capacity and provide this information to the user.

In view of the above-mentioned problem, there exists a need for a solution that can detect the remaining volume and the remaining capacity of a battery unit more quickly in a very shorter time.

Moreover, wasted batteries have a lot of plastic and metallic compounds or electrolyte solution. They can cause serious environmental pollution if not treated properly. Currently, garbage is disposed by landfill, incineration, composting, or other waste disposal means. However, waste batteries cannot be disposed by above garbage disposal. It is known that recyclable materials are contained in the used batteries and they include heavy metals which have high vale for recycling purposes. With environmental awareness among people, government's encouragement for recycling, taxes charged to battery manufacturers and importers, and subsidies to the recycling industry, the recycling rate of waste battery has increased greatly in recent years.

Currently, recycling of waste batteries is mainly done by users who send waste batteries to a recycling station. However, users are not sure whether the batteries are at its end of life or not. That is, good batteries may be sent for recycling. Further, the battery manufacturers do not know how many batteries are recycled after being produced because the battery is not trackable and no method is provided to track the consumed battery for cycling.

In view of the above-mentioned problem, there exists a need for a solution that allows the battery manufacture, the recycling company, and the environmental protection agency to monitor and track the usage and recycling status of all battery products.

### SUMMARY OF THE INVENTION

It is therefore one object of the invention to provide an apparatus for monitoring power usage status of a battery unit, comprising: a battery output voltage sampling module which is capable of being switched to electrically connect a load to the battery unit at a time of use, and is then capable of measuring and sampling the startup output current of the battery unit to thereby acquire a battery remaining volume characteristic curve, wherein the waveform of the battery remaining volume characteristic curve includes an initial transient part, a downward spike, a lowered transient part, a upward spike, and a stabilized part, and wherein the lowered transient part is a feature part whose dimensionality in area is corresponding to the remaining volume of the battery unit and whether the battery life is in end-of-life condition; digital signal processing means for calculating the area underneath the lowered transient part of the battery remaining volume characteristic curve by using an integral equation which performs integration over a time interval between the downward spike and the upward spike to thereby obtain a value that indicates the remaining volume (RV) of the battery unit; and RV-to-RC lookup means, which stores a factory-predetermined correspondence between the remaining volume (RV) and the remaining capacity (RC) for the battery unit, and which is capable of determining the remaining capacity (RC) of the battery unit in correspondence to the value of the remaining volume (RV) calculated by said signal processing means.

It is another object of the invention to provide a method for monitoring power usage status of a battery unit, comprising switching to electrically connect a load to the battery unit at a time of use; measuring and sampling the output current of the battery unit flowing through the load to thereby acquire a battery remaining volume characteristic curve, wherein the waveform of the battery remaining volume characteristic curve includes an initial transient part, a downward spike, a lowered transient part, a upward spike, and a stabilized part, and wherein the lowered transient part is a feature part whose dimensionality in area indicates the remaining volume of the battery unit and whether the battery life is in end-of-life condition; calculating the area underneath the lowered transient part of the battery remaining volume characteristic curve by using an integral equation which performs integration over a time interval between the downward spike and the upward spike to thereby obtain a value that indicates the remaining volume (RV) of the battery unit; and from a factory-predetermined correspondence between the remaining volume (RV) and the remaining capacity (RC) for the battery unit, determining the remaining capacity (RC) of the battery unit in correspondence to the value of the remaining volume (RV).

Thus, the first aspect of the present invention is an apparatus for monitoring power usage status of a battery unit, comprising: a battery output voltage sampling module which is capable of being switched to electrically connect a load to the battery unit at a time of use, and is then capable of measuring and sampling the startup output current of the battery unit to thereby acquire a battery remaining volume characteristic curve, wherein the waveform of the battery remaining volume characteristic curve includes an initial transient part, a downward spike, a lowered transient part, a upward spike, and a stabilized part, and wherein the lowered transient part is a feature part whose dimensionality in area is corresponding to the remaining volume of the battery unit and whether the battery life is in end-of-life condition; digital signal processing means for calculating the area underneath the lowered transient part of the battery remaining volume characteristic curve by using an integral equation which performs integration over a time interval between the downward spike and the upward spike to thereby obtain a value that indicates the remaining volume (RV) of the battery unit; and RV-to-RC lookup means, which stores a factory-predetermined correspondence between the remaining volume (RV) and the remaining capacity (RC) for the battery unit, and which is capable of determining the remaining capacity (RC) of the battery unit in correspondence to the value of the remaining volume (RV) calculated by said signal processing means.

According to an embodiment of the present invention, further comprising a battery ID reading module for reading an ID code from the battery unit that identifying the particular type of the battery unit; and an Internet-linking module for uploading the ID code and the remaining volume (RV) of the battery unit to a cloud-based database.

According to an embodiment of the present invention, the Internet-linking module is a wireless network link.

According to an embodiment of the present invention, the wireless network link is implemented as Wi-Fi, Bluetooth device, or near-field communication.

According to an embodiment of the present invention, the Internet-linking module is based on a cable-connected link implemented as an integrated circuit, a serial peripheral interface bus, a universal asynchronous receiver/transmitter, a universal serial bus (USB) connector, or an RS-232 serial port for accessing the cloud-based server.

According to an embodiment of the present invention, further comprising warning message generating means, which is capable of comparing the remaining capacity (RC) against a predetermined safety value; and if less than the safety value, capable of generating a warning message.

According to an embodiment of the present invention, further comprising recycling notifying message generating means, which is capable of being activated when the battery unit is no longer useable to generate a recycling notifying message to inform the user to discard the battery unit for recycling and send the recycling notifying message to the cloud-based server for browsing by battery manufacturers, recycling companies, and environmental protection agencies via the Internet.

According to an embodiment of the present invention, the remaining capacity (RC) is further converted to an aging index (AX) that indicates the aging condition of the battery unit.

The second aspect of the present invention is a method for monitoring power usage status of a battery unit, comprising (1) switching to electrically connect a load to the battery unit at a time of use; (2) measuring and sampling the output current of the battery unit flowing through the load to thereby acquire a battery remaining volume characteristic curve, wherein the waveform of the battery remaining volume characteristic curve includes an initial transient part, a downward spike, a lowered transient part, a upward spike, and a stabilized part, and wherein the lowered transient part is a feature part whose dimensionality in area indicates the remaining volume of the battery unit and whether the battery life is in end-of-life condition; (3) calculating the area underneath the lowered transient part of the battery remaining volume characteristic curve by using an integral equation which performs integration over a time interval between the downward spike and the upward spike to thereby obtain a value that indicates the remaining volume (RV) of the battery unit; and (4) from a factory-predetermined correspondence between the remaining volume (RV) and the remaining capacity (RC) for the battery unit, determining the remaining capacity (RC) of the battery unit in correspondence to the value of the remaining volume (RV).

According to a method of the present invention, further comprising acquiring an ID code of the battery unit that identifying the particular type of the battery unit; and uploading the ID code and the remaining volume (RV) of the battery unit via an Internet link to a cloud-based database.

According to a method of the present invention, the Internet link is a wireless network link.

According to a method of the present invention, the wireless network link is implemented as Wi-Fi, Bluetooth device, or near-field communication.

According to a method of the present invention, the Internet link is based on a cable-connected link implemented as an integrated circuit, a serial peripheral interface bus, a universal asynchronous receiver/transmitter, a universal serial bus (USB) connector, or an RS-232 serial port for accessing the cloud-based server.

According to a method of the present invention, further comprising comparing the remaining volume against a predetermined safety value; and if less than the safety value, generating a warning message.

According to a method of the present invention, further comprising when the battery unit is no longer useable, generating a recycling notifying message to inform the user to discard the battery unit for recycling and send the recycling notifying message to the cloud-based server for browsing by battery manufacturers, recycling companies, and environmental protection agencies via the Internet.

According to a method of the present invention, the remaining capacity (RC) is further converted to an aging index (AX) that indicates the aging condition of the battery unit.

The above and other objects, features and advantages of the invention will become apparent from the following detailed description taken with the accompanying drawings.

### BRIEF DESCRIPTION OF DRAWINGS

FIG. 1 is a block diagram of a trackable battery apparatus according to the invention;

FIG. 2 is a block and circuit diagram of the trackable battery apparatus;

FIG. 3 plots a voltage curve of sampled voltage values;

FIG. 4 plots a voltage curve of another sampled voltage values;

FIG. 5 is a flow chart of a method of tracking a trackable battery apparatus according to the invention;

FIG. 6 depicts different user ends connected to the cloud database of FIG. 5;

FIG. 7 is a schematic diagram showing the application of an apparatus designed in accordance with the invention for monitoring the power usage status of a battery unit;

FIG. 8 is a functional flow diagram showing the conceptual model of the apparatus of the invention;

FIG. 9 is a schematic diagram showing the architecture of a generic microprocessor system used to implement the apparatus of the invention;

FIG. 10A is a graph showing the battery remaining volume characteristic curve of a battery unit when fully charged at the time of production;

FIG. 10B is a graph showing the same of FIG. 4A when the battery power is half consumed;

FIG. 10C is a graph showing the same of FIG. 4A when the battery unit is near the end of the battery life;

FIG. 10D is a graph showing the same of FIG. 4A when the battery unit is no longer usable and should be discarded for recycling;

FIG. 11 is a graph showing the calculation of the area underneath the lowered transient part of the battery remaining volume characteristic curve of a battery unit;

FIG. 12 shows an example of a lookup table database which shows the correspondence between remaining volume and remaining capacity for three different types of battery products;

FIG. 13 is an activity diagram showing the interaction between the apparatus of the invention and a cloud-based server via the Internet; and

FIG. 14 is a flow diagram showing the operation performed by the apparatus of the invention.

### DETAILED DESCRIPTION OF PREFERRED EMBODIMENTS

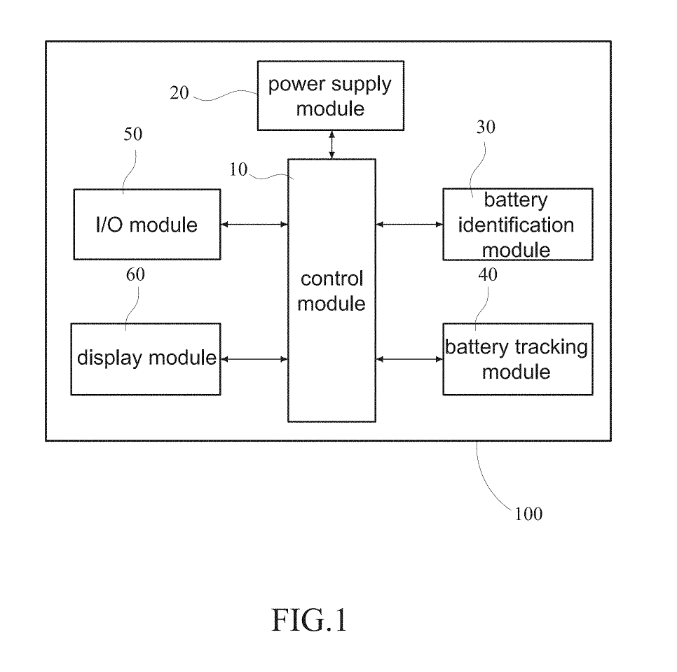

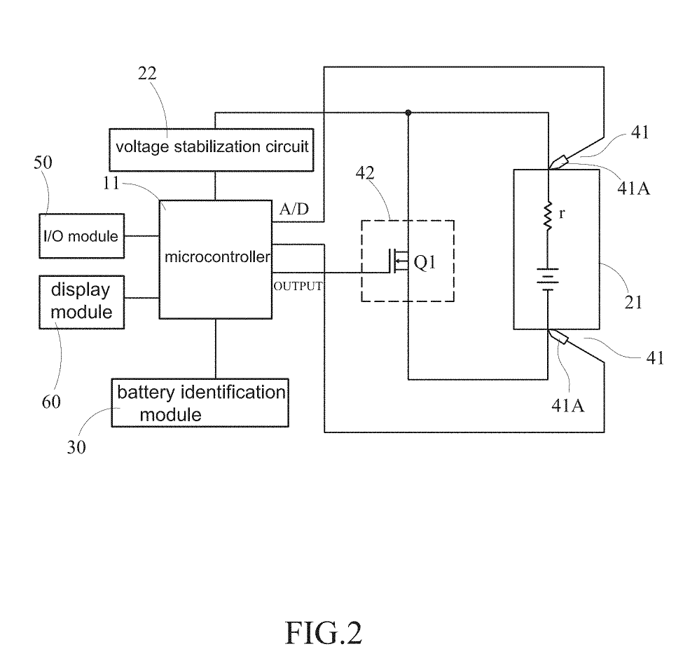

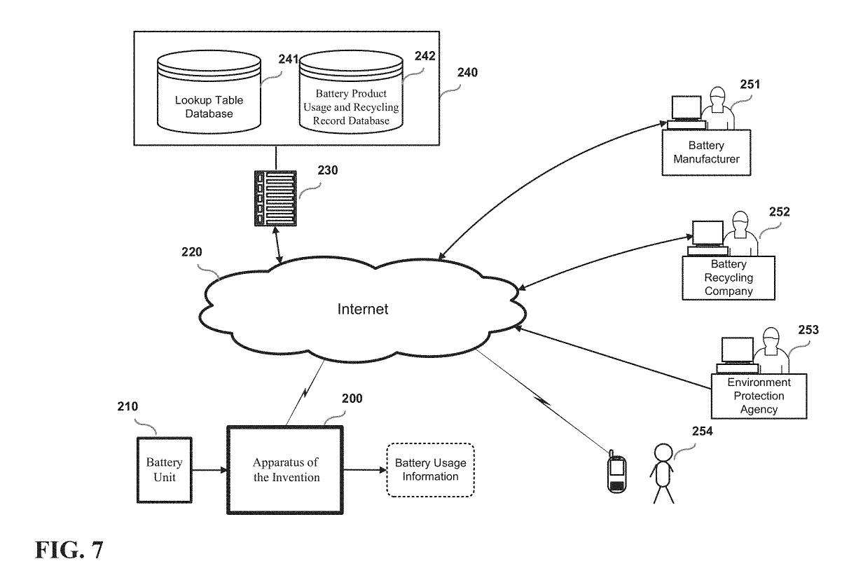

In accordance with invention, two practical embodiments are disclosed in full details in the following with reference to the accompanying drawings. The first embodiment is disclosed with reference to FIGS. 1-6, while the second embodiment is disclosed with reference to FIGS. 7-14.

### First Embodiment

Referring to FIGS. 1 to 4 and 6, a trackable battery apparatus 100 is disclosed, which comprises the following components as discussed in detail below.

A control module 10, a power supply module 20, a battery identification module 30, a battery tracking module 40, an input/output (I/O) module 50 and a display module 60 are provided. The control module 10 includes a microcontroller 11 electrically connected to the power supply module 20, the battery identification module 30, the battery tracking module 40, the I/O module 50 and the display module 60 respectively so that the microcontroller 11 can control the power supply module 20, the battery identification module 30, the battery tracking module 40, the I/O module 50 and the display module 60 respectively.

The power supply module 20 includes a voltage stabilization circuit 22 and a battery 21 for supplying power to all components of the trackable battery apparatus 100 via the voltage stabilization circuit 22.

The battery identification module 30 is electrically connected to the control module 10 and configured to generate an identification code (N) which is unique. The trackable battery apparatus 100 can be identified by the identification code (N).

The battery tracking module 40 electrically connected to the control module 10 includes a voltage sampling circuit 41 and a transient current control circuit 42. The voltage sampling circuit 41 includes two sampling circuit terminals 41A in which one is electrically interconnected an analog/digital (A/D) terminal of the microcontroller 11 and a positive terminal of the battery 21 and the other is electrically interconnected the microcontroller 11 and a negative terminal of the battery 21.

The transient current control circuit 42 includes a metal-oxide-semiconductor field-effect transistor (MOSFET) Q1 paralleled the battery 21. The MOSFET Q1 is controlled by the microcontroller 11 to serve as a switch. The MOSFET Q1 and associated circuits thereof are loads. Further, the MOSFET Q1 serves to limit transient current. Voltage values are sampled by sampling a transient current of the battery 21. Moreover, external resistor(s) can be provided to parallel the battery 21 as a load. The trackable battery apparatus 100 can track the battery 21 by using the battery tracking module 40. Further, the trackable battery apparatus 100 can be identified by using the identification code (N). For example, the trackable battery apparatus 100 is manufactured on a date D0 and has the most recently used date D1. The condition of the battery 21 can be tracked by using the battery tracking module 40.

The transient current control circuit 42 is controlled by the microcontroller 11 to conduct the MOSFET Q1 which in turn generates a transient current. The voltage sampling circuit 41 samples a voltage V01 at turning point and a reference voltage V02 at stable manner. Maximum capacity (state of charge) of the battery 21 on the date of production is labeled as h0. Available capacity (state of charge) of the battery 21 after use, labeled as hl, is compared to h0 to obtain an aging index AX.

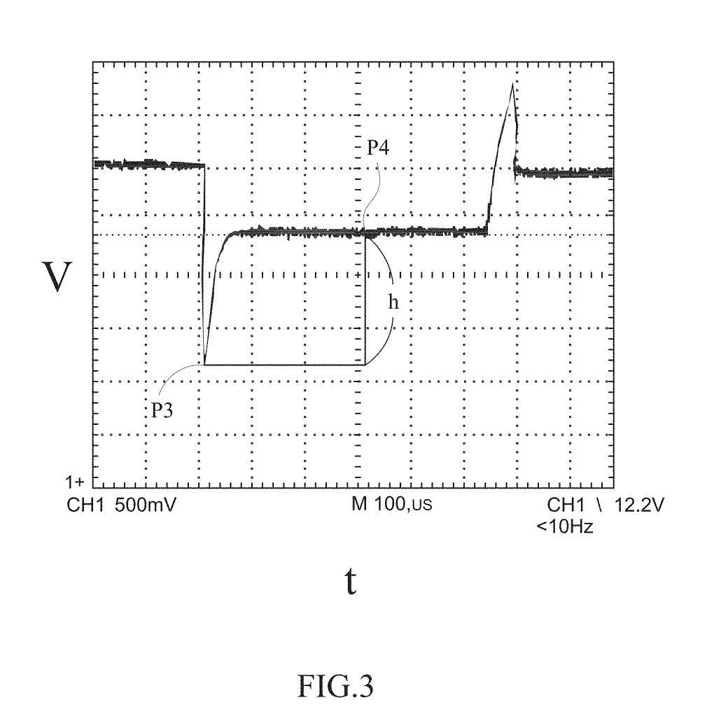

In the voltage/time curve of FIG. 3, the voltage V01 at turning point represents a minimum voltage across positive and negative terminals of the battery 21 having a date of production D0 (i.e., voltage at a turning point P3) when the MOSFET Q1 is conducted by the transient current control circuit 42. The reference voltage V02 is a voltage at a reference point P4 which is above the lowest point (i.e., the turning point P3) by a height (h). The turning point P3 is taken as a reference. The height (h) can be used for determining the remaining capacity of the battery 21.

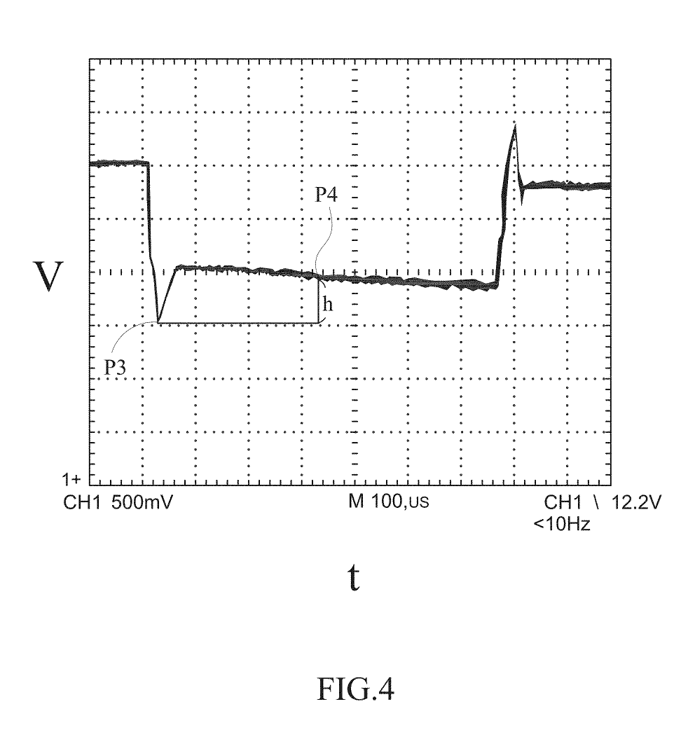

In FIG. 4, the reference point P4 is above the turning point P3 by a height (h) which is less than the height (h) of FIG. 3. Thus, the remaining capacity of the battery 21 in FIG. 4 is less than that of the battery 21 in FIG. 3. This is because the battery 21 in FIG. 4 is used more times than that in FIG. 3.

The I/O module 50 includes a wireless transmission unit for sending the aging index AX, the identification code (N), and the date of production D0 to a cloud database 70 so that a user may retrieve the aging index AX, the identification code (N), and the date of production D0 by accessing the cloud battery 70. The wireless transmission unit is Wi-Fi, Bluetooth device, or near-field communication. Alternatively, the I/O module 50 is replaced by a wire transmission unit which can be an integrated circuit, a serial peripheral interface bus, a universal asynchronous receiver/transmitter, a universal serial bus (USB) connector, or an RS-232 serial port and can access the cloud database 70.

The display module 60 can display a quick response (QR) code and store the aging index AX, the identification code (N), and the date of production D0 in the QR code. Thus, a user may retrieve the aging index AX, the identification code (N), and the date of production D0 by using the QR code.

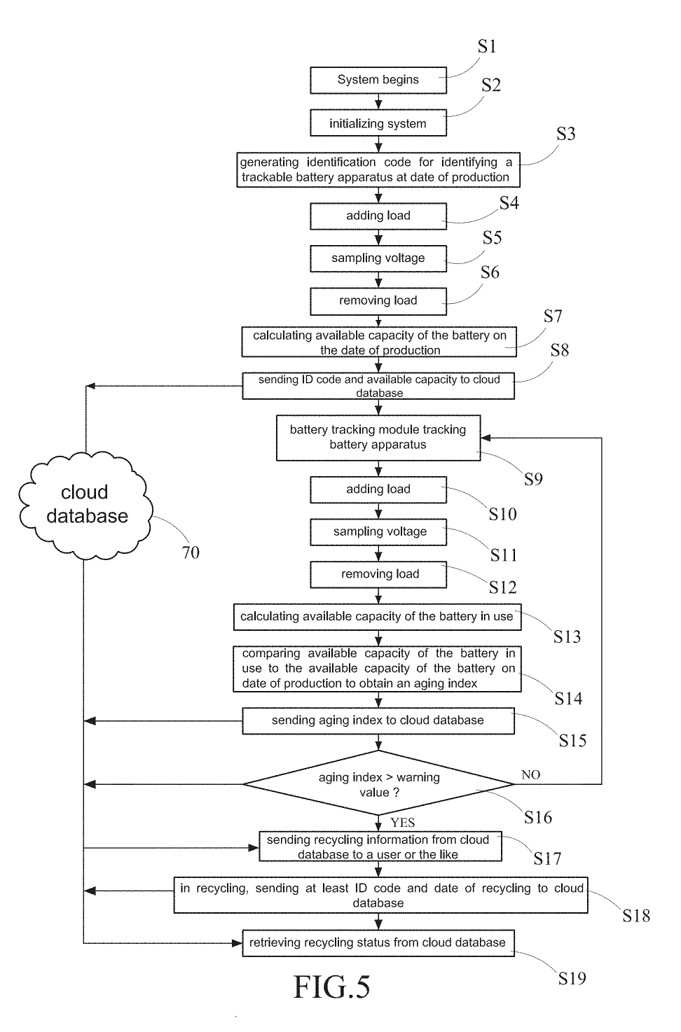

Referring to FIG. 5 in conjunction with FIGS. 1 to 4 and 6, a flow chart of a method of tracking the trackable battery apparatus 100 is illustrated. The method comprises the following steps:

Step S1: System begins with vector addresses being interrupted and software begins to run.

Step S2: System is initialized with registers and I/O pins initialized, the registers reset, interrupt vectors and timers activated, and states and initial values of each I/O pin defined.

Step S3: A unique identification code (N) is generated by a battery identification module 30 when the trackable battery apparatus 100 is manufactured. The identification code (N) is used to identify a specific trackable battery apparatus 100.

Step S4: Load is added to the system. The microcontroller 11 activates a transient current control circuit 42 to conduct the MOSFET Q1 which in turn generates a transient current.

Step S5: Voltage is sampled. The voltage sampling circuit 41 measures the voltage at the turning point P3 when the trackable battery apparatus 100 being produced and the reference voltage at the reference point P4. Also, a transient current is generated by the transient current control circuit 42 at the date of production D0. The voltage sampling circuit 41 measures the voltage V01 at turning point and also the reference voltage V02 at stable manner when the trackable battery apparatus 100 is being produced.

Step S6: Load is removed. The microcontroller 11 deactivates the transient current control circuit 42 to turn off the MOSFET Q1.

Step S7: The battery tracking module 40 calculates a difference between the voltage at turning point and the reference voltage at stable manner so as to obtain an available capacity of the battery on the date of production D0. Specifically, the battery tracking module 40 calculates a difference between the voltage V01 at turning point and the reference voltage V02 at stable manner so as to obtain an available capacity h0 of the battery 21 in the trackable battery apparatus 100 on the date of production D0.

Step S8: Additionally, the I/O module 50 sends the identification code (N) and available capacity (h0) of the battery 21 to a cloud database 70 as a record.

Step S9: The battery tracking module 40 may track the trackable battery apparatus 100.

Step S10: Load is added to the system. The microcontroller 11 activates the transient current control circuit 42 to conduct the MOSFET Q1 which in turn generates a transient current.

Step S11: The voltage sampling circuit 41 measures the voltage at turning point and the reference voltage. Specifically, a user may activate the transient current control circuit 42 to generate a transient current at date D1 and activate the voltage sampling circuit 41 to measures the voltage V11 at turning point, and the reference voltage V12 at stable manner.

Step S12: Load is removed. The microcontroller 11 deactivates the transient current control circuit 42 to turn off the MOSFET Q1.

Step S13: The battery tracking module 40 calculates a difference between the voltage at turning point and the reference voltage at stable manner, so as to obtain an available capacity of the battery on the date of use D1. That is, the battery tracking module 40 calculates a difference between the voltage V11 at the turning point and the reference voltage V12 at stable manner, so as to obtain an available capacity (hl) of the battery 21 in the trackable battery apparatus 100 on the date of use D1.

Step S14: Available capacity of the battery after use is compared to the available capacity to obtain an aging index. Specifically, available capacity (hl) of the battery 21 on the date of use D1 is divided by the available capacity (h0) on the date of production to obtain an aging index AX in terms of percentage for determining the aging state of the battery 21.

Step S15: Aging index is sent to the cloud database. Specifically, the I/O module 50 sends the aging index AX to the cloud database 70 by means of wireless or wire medium. A user or the like may access the cloud database 70 to retrieve the identification code (N) which is in turn used to retrieve the aging index AX.

Step S16: It is determined whether recycling of the battery is necessary based on a warning value from the manufacturer. Specifically, the aging index AX is compared to the warning value. The comparison result and the identification code (N) are sent to the cloud database 70. The flow chart goes to step S17 if the comparison is positive. Otherwise, the flow chart returns to step S9.

Step S17: Sending battery recycling information. Specifically, information of the trackable battery apparatus 100 having a consumed battery 21 is sent from the cloud database 70 to a user or the like.

Step S18: Battery recycled. A trackable battery apparatus 100 having the identification code (N) is sent to a recycling station. Further, the identification code (N) and the recycling date D2 are sent to the cloud database 70 as a record.

Step S19: Recycling status. Specifically, a battery user, a battery manufacturer, a recycling company, or an environmental protection agency in charge of battery recycling may be aware of the recycling status of a recycled trackable battery apparatus 100 by accessing the cloud database 70 to retrieve the identification code (N) and the recycling date D2 of the trackable battery apparatus 100.

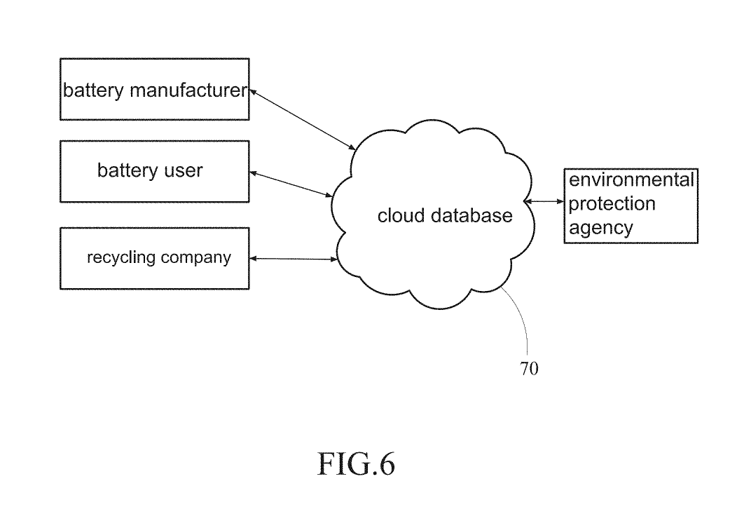

Referring to FIG. 6 specifically, a battery manufacturer, a battery user, a recycling company, and an environmental protection agency in charge of battery recycling are capable of accessing the cloud database 70 to retrieve information about a recycled battery.

### Second Embodiment

The second embodiment of the invention is disclosed in full details in the following with reference to FIGS. 7-14.

FIG. 7 is a schematic diagram showing the application of an apparatus 200 designed in accordance with the invention for monitoring the power usage status of a battery unit 210, including the remaining volume and the remaining capacity of the battery unit as well as the recycling status of the battery unit 210. In application, the battery unit 210 can be any type of battery that is used for supplying electric power to any machine or equipment, such as electric car, electric motorcycle notebook computer, mobile phone, or any type of electronic equipment.

The apparatus of the invention 200 can be linked via the Internet 220 to a server 230 provided by the manufacturer of the battery unit 210. The server 230 is preinstalled with a battery product database module 240 which contains a lookup table database 241 and a battery product usage and recycling record database 242.

In operation, the apparatus of the invention 200 allows the user to check the usage information about the battery unit 210 at any time of use. The usage information includes the remaining volume and the remaining capacity of the battery unit 210 as well as whether the battery unit 210 is near the end of the battery life and no longer useable such that the battery unit 210 should be replaced and discarded for recycling. If the remaining capacity of the battery unit 210 is only 30 minutes or 10 minutes), the apparatus of the invention 200 will display a warning message to inform the user to take necessary actions to recharge or replace the battery unit 210. If the battery unit 210 is no longer usable and should be discarded for recycling, the apparatus of the invention 200 will display a notifying message to inform the user to replace and discard the battery unit 210 for recycling.

In addition, if the battery unit 210 is no longer usable and should be discarded for recycling, the apparatus of the invention 200 will send a notifying message to the server 230 where the battery product usage and recycling record database 242 is updated to show that the battery unit 210 is out of service and being recycled. This allows the battery manufacture 251, the recycling company 252, the environmental protection agency 253, and the battery user 254 to gain access via the Internet 220 to the server 230 to browse the information stored in the battery product usage and recycling record database 242.

The apparatus of the invention 200 can be linked to the Internet 220 either by means of a wireless link or a cable-connected link. In practice, the wireless link can be selected from any 4G or 3G wireless networking facilities, such as General Packet Radio Service (GPRS). Bluetooth, Wi-Fi, Zigbee, Global System far Mobile Communications (GSM), Access Point (AP), to name just a few.

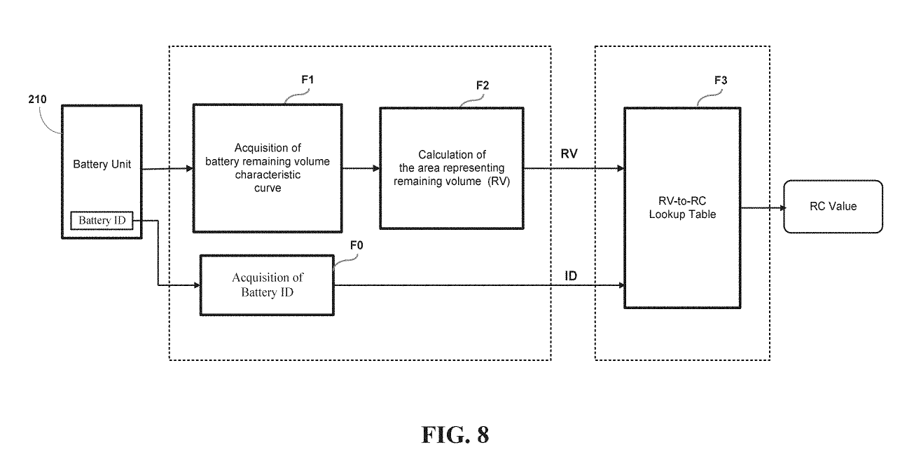

FIG. 8 is a functional flow diagram showing the conceptual model of the operation performed by the apparatus of the invention 200. As shown, the functional flow diagram includes an initial function F0 for acquiring an ID code from the battery unit 210; a first function F1 for detecting and acquiring a battery remaining volume characteristic curve of the battery unit 210; a second function F2 for determining the remaining volume (RV) of the battery unit 210 based on the acquired battery remaining volume characteristic curve of the battery unit 210; and a third function F3 for determining the remaining capacity (RC) of the battery unit 210 by the use of a predetermined lookup table that shows the correspondence between the remaining volume (RV) and the remaining capacity (RC) of the battery unit 210.

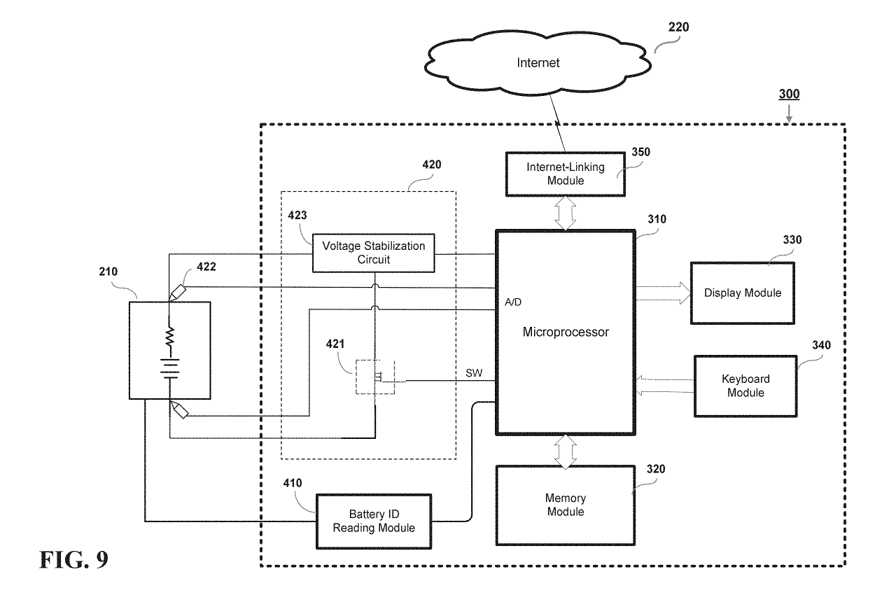

Referring to FIG. 9, the functions F0-F3 can be practically implemented by using a generic microprocessor system 300, which includes a microprocessor 310, a memory module 320, a keyboard input module 330, a display module 340, and an Internet-linking module 350. The microprocessor 310 is used to serve as a control module for controlling the operation of the apparatus of the invention 200. The memory module 320 is used to store a set of digital signal processing programs and control programs that control the operation of the apparatus of the invention 200. The keyboard input module 340 allows the user to input commands and data to the apparatus of the invention 200. The display module 330 is used to display and inform the user of the battery usage information, such as the remaining volume, remaining capacity, low-power warning message, and out-of-service notifying message. The Internet-linking module 350 is used to link the microprocessor system 300 via the Internet 220 to the server 230 by means of either via a wireless link or a cable-connected link. The wireless link can be can be selected from any 4G or 3G wireless network linking facilities, such as GPRS (General Packet Radio Service), Bluetooth, Wifi, Zigbee, GSM, AP, to name just a few. The cable-connected link can be USB, RS-232, or any type of facility that can be linked to the Internet 220.

In addition, in order to fully implement the apparatus of the invention 200, the microprocessor system 300 is further installed with a battery ID reading module 410 and a battery output voltage sampling module 420.

With the microprocessor system 300, the initial function F0 shown in FIG. 8 is implemented by the battery ID reading module 410 which is capable of reading an ID code of the battery unit 210. The battery ID code can be, for example, a bar code printed on the battery unit 210 that can be scanned, or a binary code stored in an IC chip embedded in the battery unit 210.

The first function F1 shown in FIG. 8 can be implemented together by the battery output voltage sampling module 420 and an embedded A/D function in the microprocessor 310. The battery output voltage sampling module 420 includes a switching element 421, such as a transistor, and a pair of probes 422. In operation, at the startup of the battery unit 210, the microprocessor 310 can generate an output signal OUTPUT to switch on the switching element 421, thereby allowing the battery unit 210 to output a transient current which flows through the switching element 421. Meanwhile, the probes 422 can detect and sample the startup output voltage of the battery unit 210 and transfer the sampled voltage to the A/D port of the microprocessor 310 which can use an embedded A/D converter circuit to convert the sampled voltage into digital form and thereby obtain a battery remaining volume characteristic curve of the battery unit 210.

Next, the second function F2 shown in FIG. 8 is implemented by using a set of digital signal processing programs that are preinstalled in the memory module 320 and can be executed by the microprocessor 310. These digital signal processing programs are capable of processing the digitized characteristic curve to thereby determine the remaining volume (RV) of the battery unit 210.

Finally, the third function F3 is implemented by using the lookup table database 241 stored in the cloud-based server 230 and the Internet-linking module 350 to upload the data (ID, RV) via the Internet 220 to the server 230 where the lookup table database 241 is used to determine the remaining capacity (RC) corresponding to the uploaded data (ID, RV). The retrieved RC value is then downloaded via the Internet 220 back to the microprocessor system 300 where the downloaded RC value is displayed on the display module 340 to inform the user of the remaining capacity of the battery unit 210.

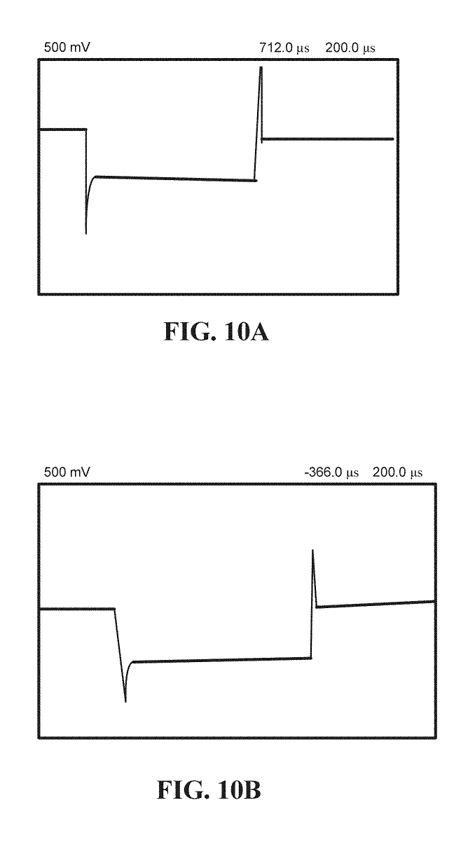

Referring to FIGS. 10A-10D, there are four possible shapes of the battery remaining volume characteristic curve, which are respectively as shown. FIG. 10A shows a battery remaining volume characteristic curve that indicates that the battery unit 210 is fully charged. FIG. 10B shows the same when the fully volume of the battery unit 210 is partly consumed. FIG. 10C shows the same when the battery unit 210 is near the end of the battery life and is about to be discarded for recycling. FIG. 10C shows the same when the battery unit 210 is no longer usable and in end-of-life condition and thus should be discarded for recycling. The curve shown in FIG. 10D is sampled by using a larger voltage of 2.0 V which is different from the smaller 500 mV used for sampling the curves shown in FIGS. 10A-10C because when the battery is no longer usable, it requires a larger magnitude of sampling voltage to acquire the waveform.

Accordingly, based on the graphs shown in FIGS. 10A-10D, we can determine the remaining volume or the remaining capacity of the battery unit 210, and also can determine whether the battery unit 210 is still usable or is no longer usable and should be discarded for recycling.

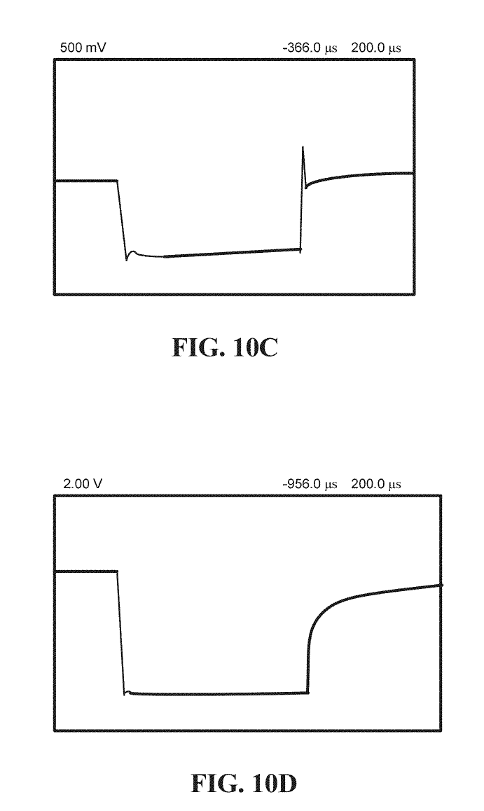

Referring to FIG. 11, when the battery unit 210 is still usable, its battery remaining volume characteristic curve will be as shown, which includes an initial transient part L1, a downward spike P1, a lowered transient part L2, an upward spike P2, and a stabilized part L3. This graph shows that at the startup when the battery unit 210 is connected to supply power, its output voltage will successively undergo the initial transient part L1, the downward spike P1, the lowered transient part L2, and the upward spike P2 until finally reaching the stabilized part L3.

It is an important aspect of the invention that the remaining volume (RV) of the battery unit 210 can be determined by calculating the dimensionality of the area underneath the lowered transient part L2 by integration over the time interval from t₁ to t₂, where t₁ is the time point when the downward spike P1 occurs, and t₂ is the time point when the upward spike P2 occurs. In the curve of FIG. 11, it is highly worthy to note that the time interval from t₁ to t₂ is a very short instant of time that is as small as 1 ms (millisecond) or even less. This means that the detection of the remaining volume (RV) can be achieved very quickly in a very short instant of time as small as 1 ms or even less.

The area beneath the lowered transient part L2, which represents the remaining volume (RV) of the battery unit 210, can be calculated by the following integral equation:

RV=∫ₜ₁^{t2}f(x)dx=F(x)+C fₐ

wherein the time interval from t1 to t2 is a very short instant of time that is as small as 1 ms or even less, and C is a constant whose value is dependent on the ambient temperature, voltage, and different types or brands of batteries. In practice, the integration can be implemented by using a set of digital signal and graphic processing programs to calculate the area underneath the lowered transient part L2 that is proportional to the remaining volume of the battery unit 210, and thus can be used as an indication of the remaining volume of the battery unit 210.

Since different types or brands of batteries could have different values of C, the value of C in each different type or brand of battery unit is determined in advance to find the correspondence between RV and RC for each different type or brand of battery unit. The data are then used to build an RV-to-RC lookup table that shows the correspondence between RV and RC for all various different types or brands of battery units, and each particular type or brand of battery unit is associated with a unique ID code. Therefore, the battery unit 210 is embedded with a unique ID code which is uploaded together with its RV value to the cloud-based server 230, where the ID code is used for accessing the lookup table associated with the particular type and brand of the battery unit 210, such that the remaining capacity (RC) corresponding to the remaining volume (RV) can be retrieved from the associated lookup table.

However, the RV value obtained from the area underneath the lowered transient part L2 is unable to be directly used to indicate the remaining capacity of the battery unit 210. This is because that different types of battery products could have different characteristic relationships between the remaining volume (RV) and the remaining capacity (RC). By the industry standard, the remaining capacity (RC) is defined as the number of minutes during which a fully-charged battery at 80° F. (25 Celsius degrees) will discharge 25 amps until the battery voltage drops below 10.5 volts. Therefore, the remaining capacity (RC) of the battery unit 210 can be used to calculate the remaining discharge time of the battery unit 210 by detecting the duration of time in which the battery unit 210 will discharge 25 A until the battery voltage drops below 10.5V. The value of the remaining capacity (RC) can be determined by further querying a factory-predetermined lookup table database 241, which is calculated and provided in the cloud-based server 230 and which shows the correspondence between the remaining volume (RV) and the remaining capacity (RC) of the battery unit 210. To query the lookup table database 241, the apparatus of the invention 200 also needs the ID code of the battery unit 210.

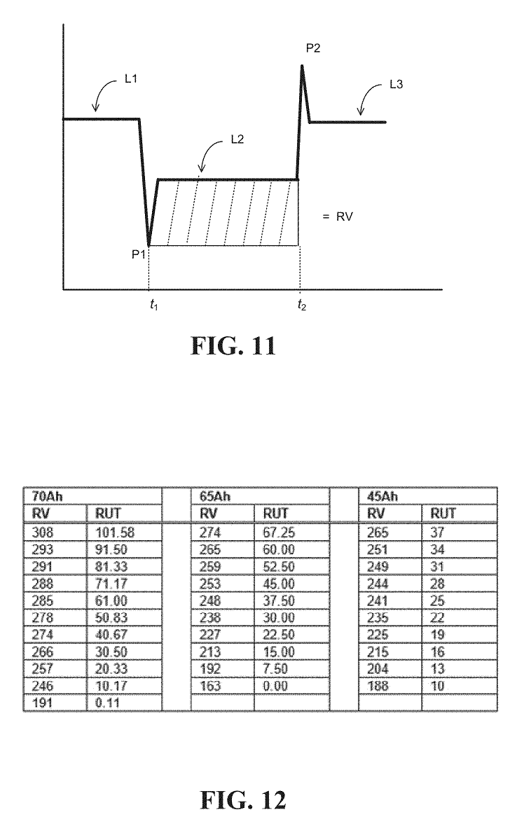

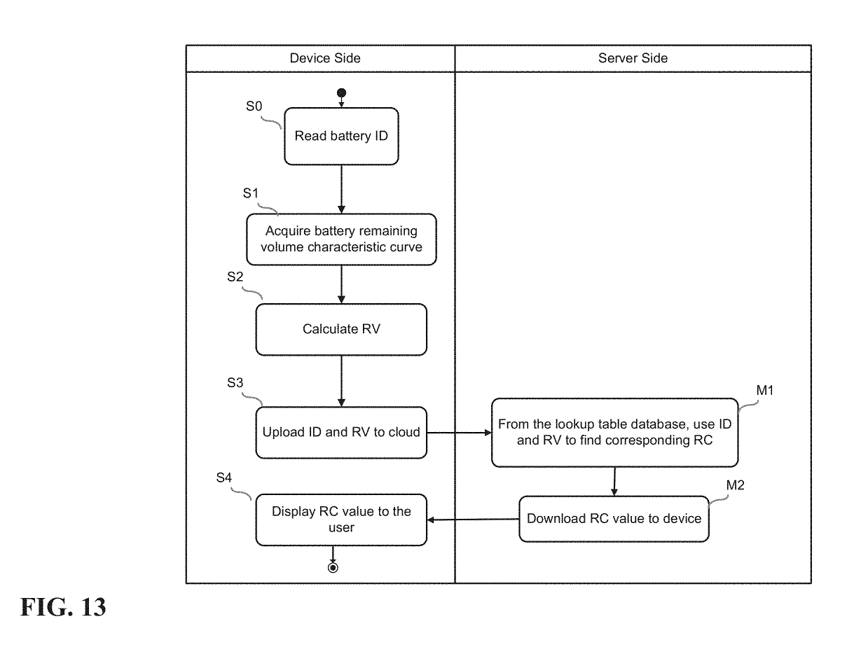

FIG. 12 shows an example of the content of the lookup table database 241. As shown, the lookup table database 241 showing factory-predetermined correspondences between the remaining volume (RV) and the remaining capacity (RC). In FIG. 13, for example, shows an RV-to-RC lookup table for a battery type of 70 Ah.

In order to query the lookup table, the ID code of the battery unit 210 is first used as key to gain access to the associated lookup table. For example, if RV=285 and the ID code shows that the battery unit 210 belongs to the 70 Ah battery type, the Table accessed and the RC value corresponding to RV=285 is found to be 61.00, indicating that the remaining capacity of the battery unit 210 is 61 minutes. If RV=280, then the corresponding RC value can be calculated by interpolating between 50.83 and 61.00 and found to be about 55, indicating that the remaining capacity of the battery unit 210 is about 55 minutes.

On the server side, the retrieved RC value is then downloaded via the Internet 220 back to the apparatus of the invention 200 where the RC value is displayed to the user. If the RC value is overly low, for example only 30 minutes or 10 minutes, the apparatus of the invention 200 will also display a warning message to inform the user (or to the autopilot or car service), to take necessary actions to recharge or replace the battery unit 210.

The apparatus of the invention 200 is characterized in that it is capable of detecting the remaining volume (RV) and the remaining capacity (RC) of the battery unit 210 quickly in a very short time, as short as 1 ms (millisecond), after the startup of the battery unit 210.

The following is a detailed description of the application of the apparatus of the invention 200 and the cloud-based system shown in FIG. 7.

Referring to FIG. 13, at the startup of the battery unit 210 at a time of use when the battery unit 210 is switched on to supply power, the apparatus of the invention 200 first perform the step S0 to read the ID code of the battery unit 210. Next, the battery output detecting circuit 110 performs the step S1 to detect and acquire a battery remaining volume (RV) characteristic curve of the battery unit 210, and then performs the next step S2 to determine the remaining volume (RV) of the battery unit 210 based on the battery remaining volume characteristic curve by calculating the area underneath the lowered transient part L2 of the battery remaining volume (RV) characteristic curve as illustrated in FIG. 11. In the next step S3, the data (ID, RV) are uploaded via the Internet 220 to the server 230 for further processing.

On the server side, the server 230 first perform the step M1 to use the received battery ID code as key to gain access to the corresponding lookup table associated with the battery unit 210, and then the RV value is used as keyword to find and retrieve the corresponding RC value. In the next step M2, the retrieved RC value is downloaded via the Internet 220 to the apparatus of the invention 200.

On the device side, the apparatus of the invention 200 performs the step S4 to display the downloaded remaining capacity (RC) value to the user so as to inform the user of the remaining capacity of the battery unit 210. If the remaining capacity of the battery unit 210 is only 10 minutes or 5 minutes, a warning message is also displayed to notify the user to take necessary actions to recharge or replace the battery unit 210 immediately.

Further, if the apparatus of the invention 200 detects that the battery unit 210 is no longer usable and should be discarded for recycling, it will send the date on which the battery unit 210 is discarded for recycling to the server 230 where the battery product usage and recycling record database 242 is updated to show the information that the battery unit 210 is no longer usable and being recycled. This allows the battery manufacture 251, the recycling company 52, the environmental protection agency 53, and the battery user 54 to gain access via the Internet 220 to the server 230 to browse the information stored in the battery product usage and recycling record database 242.

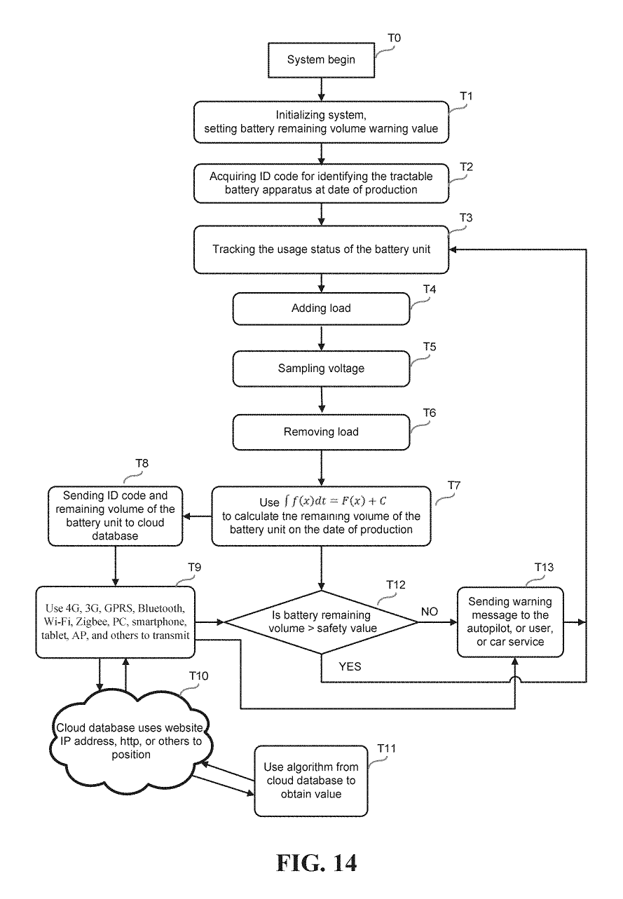

FIG. 14 is a flow diagram showing more detailed operation performed by the apparatus of the invention 200 in accordance with the invention.

As shown, in the initial step T0, the system of the apparatus of the invention 200 is started. Next, in the step T1, the apparatus of the invention 200 is initialized, and a warning value is set for the battery remaining volume. At the same time, set a counting reference Number (n) from 0 (zero) for further counting usage. In the next step T2, the ID code of the apparatus of the invention 200 is acquired for identifying the particular type and brand of the battery unit 210. In the next step T3, the apparatus of the invention 200 is started to track the usage status of the battery unit 210. In the next step T4, a load is added to the battery unit 210, and then in the next step T5, the output voltage of the battery unit 210 is sampled to obtain a battery remaining volume characteristic curve. In the next step T6, the load is removed. And one frequency number (1) is added to (n) for each follow-up statistics.

Further, in the next step T7, the following integral equation:

∫ₜ₁^{t2}f(x)dx=F(x)+C

is performed on the battery remaining volume characteristic curve to calculate the remaining volume (RV) of the battery unit 210. In the next step T8, the ID code and the calculated remaining volume are collected for uploading to the cloud-based server 230, and in the next step T9, the data are sent to the cloud-based server 230 via an Internet link, such as 4G, 3G, GPRS, Bluetooth, Wi-Fi, Zigbee, PC, smartphone, tablet, AP, or the like. In the next step T10, the cloud-based server 230 uses website, IP address, http, or others to position the battery product database module 40. In the next step T11, the corresponding remaining capacity (RC) is retrieved from the lookup table database 241. In the step T12, it is checked whether the remaining volume is greater than a safety value. If YES, the procedure returns to step T3; and otherwise, if NO, there procedure goes to step T13, in which a warning message is sent to the autopilot, user, or car service, so that necessary actions can be taken to recharge or replace the battery unit 210. The procedure also returns to step T3 for further use stage to repeatedly perform the steps T3-T13 for continuously monitoring the power usage status of the battery unit 210.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. An apparatus for monitoring power usage status of a battery unit, comprising:
a battery output voltage sampling module which is capable of being switched to electrically connect a load to the battery unit at a time of use, and is then capable of measuring and sampling the startup output current of the battery unit to thereby acquire a battery remaining volume characteristic curve, wherein the waveform of the battery remaining volume characteristic curve includes an initial transient part, a downward spike, a lowered transient part, a upward spike, and a stabilized part, and wherein the lowered transient part is a feature part whose dimensionality in area is corresponding to the remaining volume of the battery unit and whether the battery life is in end-of-life condition;
digital signal processing means for calculating the area underneath the lowered transient part of the battery remaining volume characteristic curve by using an integral equation which performs integration over a time interval between the downward spike and the upward spike to thereby obtain a value that indicates the remaining volume (RV) of the battery unit; and
RV-to-RC lookup means, which stores a factory-predetermined correspondence between the remaining volume (RV) and the remaining capacity (RC) for the battery unit, and which is capable of determining the remaining capacity (RC) of the battery unit in correspondence to the value of the remaining volume (RV) calculated by said signal processing means.

2. The apparatus of claim 1, further comprising:
a battery ID reading module for reading an ID code from the battery unit that identifying the particular type of the battery unit; and
an Internet-linking module for uploading the ID code and the remaining volume (RV) of the battery unit to a cloud-based database.

3. The apparatus of claim 2, wherein said Internet-linking module is a wireless network link.

4. The apparatus of claim 3, wherein said wireless network link is implemented as Wi-Fi, Bluetooth device, or near-field communication.

5. The apparatus of claim 2, wherein said Internet-linking module is based on a cable-connected link implemented as an integrated circuit, a serial peripheral interface bus, a universal asynchronous receiver/transmitter, a universal serial bus (USB) connector, or an RS-232 serial port for accessing the cloud-based server.

6. The apparatus of claim 1, further comprising:
warning message generating means, which is capable of comparing the remaining capacity (RC) against a predetermined safety value; and if less than the safety value, capable of generating a warning message.

7. The apparatus of claim 1, further comprising:
recycling notifying message generating means, which is capable of being activated when the battery unit is no longer useable to generate a recycling notifying message to inform the user to discard the battery unit for recycling and send the recycling notifying message to the cloud-based server for browsing by battery manufacturers, recycling companies, and environmental protection agencies via the Internet.

8. The apparatus of claim 1, wherein the remaining capacity (RC) is further converted to an aging index (AX) that indicates the aging condition of the battery unit.

9. A method for monitoring power usage status of a battery unit, comprising:
(1) switching to electrically connect a load to the battery unit at a time of use;
(2) measuring and sampling the output current of the battery unit flowing through the load to thereby acquire a battery remaining volume characteristic curve, wherein the waveform of the battery remaining volume characteristic curve includes an initial transient part, a downward spike, a lowered transient part, a upward spike, and a stabilized part, and wherein the lowered transient part is a feature part whose dimensionality in area indicates the remaining volume of the battery unit and whether the battery life is in end-of-life condition;
(3) calculating the area underneath the lowered transient part of the battery remaining volume characteristic curve by using an integral equation which performs integration over a time interval between the downward spike and the upward spike to thereby obtain a value that indicates the remaining volume (RV) of the battery unit; and
(4) from a factory-predetermined correspondence between the remaining volume (RV) and the remaining capacity (RC) for the battery unit, determining the remaining capacity (RC) of the battery unit in correspondence to the value of the remaining volume (RV).

10. The method of claim 9, further comprising:
acquiring an ID code of the battery unit that identifying the particular type of the battery unit; and
uploading the ID code and the remaining volume (RV) of the battery unit via an Internet link to a cloud-based database.

11. The method of claim 10, wherein the Internet link is a wireless network link.

12. The method of claim 11, wherein the wireless network link is implemented as Wi-Fi, Bluetooth device, or near-field communication.

13. The method of claim 10, wherein the Internet link is based on a cable-connected link implemented as an integrated circuit, a serial peripheral interface bus, a universal asynchronous receiver/transmitter, a universal serial bus (USB) connector, or an RS-232 serial port for accessing the cloud-based server.

14. The method of claim 9, further comprising:
comparing the remaining volume against a predetermined safety value; and if less than the safety value, generating a warning message.

15. The method of claim 9, further comprising:
when the battery unit is no longer useable, generating a recycling notifying message to inform the user to discard the battery unit for recycling and send the recycling notifying message to the cloud-based server for browsing by battery manufacturers, recycling companies, and environmental protection agencies via the Internet.

16. The method of claim 9, wherein the remaining capacity (RC) is further converted to an aging index (AX) that indicates the aging condition of the battery unit.
